(19) United States
(12) Patent Application Publication
(10) Pub. No.: US 2018/0069405 A1
(43) Pub. Date: Mar. 8, 2018

(54) Multi-Source Energy Harvesting Device

(71) Applicant: SPAWAR Systems Center Pacific, San Diego, CA (US)

(72) Inventors: Ryan P. Lu, San Diego, CA (US); Ayax D. Ramirez, Chula Vista, CA (US); Bienvenido Melvin L. Pascoguin, La Mesa, CA (US)

(73) Assignee: United States of America as represented by Secretary of the Navy, San Diego, CA (US)

(21) Appl. No.: 15/260,005

(22) Filed: Sep. 8, 2016

(51) Int. Cl. H02J 3/46; H02N 2/18; H02J 50/10; H02J 3/38; H02S 40/38; H02J 7/02; H02J 50/20; A45B 25/18; A45B 3/00; A45B 21/00; A45B 9/04

(52) U.S. Cl. CPC H02J 3/46; H02N 2/186; H02J 50/10; H02J 3/383; H02J 3/386; H02S 40/38; A45B 2200/1027; H02J 50/20; A45B 25/18; A45B 3/00; A45B 21/00; A45B 9/04; H02J 7/025

(57) ABSTRACT

A multi-source energy harvesting system, method and device are disclosed. The system, method and device incorporate multiple energy harvesting technologies to charge personal electronic devices. Solar, rain, wind, electromagnetic and radio frequency energy may be harvested using this system, method and device. A polymer solar cell may be used to harvest solar energy. Polymer piezoelectric materials may be used to harvest rain and wind energy. Inductive charging may be used to harvest electromagnetic energy.

### STATEMENT OF GOVERNMENT INTEREST FEDERALLY-SPONSORED RESEARCH AND DEVELOPMENT

The United States Government has ownership rights in this invention. Licensing inquiries may be directed to the Office of Research and Technical Applications, Space and Naval Warfare Systems Center, Pacific, Code 72120, San Diego, Calif., 92152; telephone (619)553-5118; email: ssc_pac_t2@navy.mil. Reference Navy Case No. 102,553.

### BACKGROUND OF THE INVENTION

### Field of Invention

This disclosure relates to energy harvesting, and more particularly, energy harvesting from multiple sources.

### Description of Related Art

Sustainable energy sources have become increasingly important. Polymer solar cells are now commercially available due to recently achieved efficiencies of 9.2%. Silicon solar cells have also been used. However, although silicon solar cells have higher efficiencies at 20% and III-V compound semiconductor solar cells at 40%, the low cost to manufacture via roll-to-roll printing on flexible material may make polymer solar cells more enticing to the consumer. Recent challenges of reliability of polymer solar cells have been overcome with an inverted structure. See Zhicai He, Chengmie Zhong, Shijian Su, Miao Xu, Hongbin Wu, Yong Cao, “Enhanced power conversion efficiency in polymer solar cells using an inverted device structure,” Nature Photonics, 2012; 6:591. The contents of this article are hereby incorporated by reference as if fully set forth.

Previously, polymer solar cells lost half of their initial efficiency after 10 days. The new inverted structure has shown that it retains 95% of its efficiency after 62 days. The new inverted structure also has shown that it can harvest more photons than previous device structures. Therefore, the new inverted structure may generate a higher electric current density of 17.2 mA/cm2, compared to 15.4 mA/cm2 for the regular device structure. The new inverted device structure utilizes the conjugated polymer PFN as an interlayer between the ITO substrate and the photoactive layer which can provide both ohmic contact for electron extraction and optimize photon harvest.

Outside of solar energy, other forms of energy have been harvested and used to provide electrical power. For example, polymer piezoelectric materials such as PVDF have recently shown that they can harvest the kinetic energy from raindrops. See Romain Guigon, Jean-Jacques Chaillout, Thomas Jager, Ghislain Despesse, “Harvesting raindrop energy: theory,” Smart Mater. Struct. 2008; 17:015038; and Romain Guigon, Jean-Jacques Chaillout, Thomas Jager, Ghislain Despesse. “Harvesting raindrop energy: experimental study.” Smart Mater. Struct. 2008; 17:015039. The contents of these articles are hereby incorporated by reference as if fully set forth.

Piezoelectric materials may produce energy when subjected to physical stresses. Experimental studies have shown that it is possible to recover up to 1 uW of instantaneous power in the worst case scenario, while simulations show up to 12 mW from a rain drop that is five millimeters (mm) in diameter. Stresses on the piezoelectric material due to wind shear can also produce electricity.

Inductive energy harvesting can be achieved using a tightly wound coil of wires around a tubular structure and magnet moving through the tube. A change in magnetic field will create an electrical current flow in the coil of wires. Harvesting energy from RF signals in space has been shown to be possible through commercially available chips. See A. M. Zungeru et al., Radio Frequency Energy Harvesting and Management for Wireless Sensor Networks, Department of Electrical and Electronics Engineering at The University of Nottingham. The contents of this article are hereby incorporated by reference as if fully set forth. A monopole antenna can receive RF signals where the length of the antenna determines the wavelength of the signal it can capture. Long antennas are needed for long radio wavelengths and short ones can capture short wavelengths. Additionally, it has been shown that micro-electromechanical devices can harvest energy from the RF spectrum. There is a need for an energy harvesting system that can harvest available energy from multiple sources.

With the rise in use of personal electronic devices, there has also been an increase in the need for mechanisms to recharge these devices. Personal electronic devices may be used in locations where electricity is not available. Energy harvesting may be useful in situations where the user moves from location to location. For example, a hiker may need to recharge one or more personal electronic devices at one location. The hiker may then move to another location, where the hiker also needs to recharge one or more electronic devices. Under these circumstances, it may be desirable to have an energy harvesting system that is transportable by an individual from one location to another. Accordingly, there is a need for a mechanism for recharging personal electronic devices that does not rely on traditional sources of electricity.

### BRIEF SUMMARY OF INVENTION

The present disclosure addresses the needs noted above by providing a system, method and umbrella apparatus for harvesting multiple sources of energy.

In accordance with one embodiment of the present disclosure, a multi-source energy harvesting system is provided. The system comprises a solar energy harvesting device, and a kinetic energy harvesting device that includes a polymer piezoelectric material. The system further comprises an electromagnetic energy harvesting device, and a charging port capable of charging a personal electronic device. The multi-source energy harvesting system also includes a rechargeable battery system configured to supply electrical power to the charging port. The rechargeable battery system is operably coupled to the charging port, the solar energy harvesting device, the kinetic energy harvesting device and the electromagnetic energy harvesting device. The multi-source energy harvesting system is capable of converting harvested energy into electrical energy. The system is capable of storing the electrical energy in the rechargeable battery, or consuming the electrical energy to charge one or more personal electronic devices.

These, as well as other objects, features and benefits will now become clear from a review of the following detailed description, the illustrative embodiments, and the accompanying drawings.

### BRIEF DESCRIPTION OF DRAWINGS

FIG. 1 illustrates the layer structure of an umbrella device comprised of a polymer solar cell and a kinetic energy harvesting device in accordance with one embodiment of the present disclosure.

FIG. 2 is a fragmentary and sectional view of an umbrella device in accordance with one embodiment of the present disclosure.

FIG. 3 is a schematic of a handle and shaft for an umbrella device in accordance with one embodiment of the present disclosure.

FIG. 4 is a block diagram of an energy storage flow diagram in accordance with one embodiment of the present disclosure.

### DETAILED DESCRIPTION

Disclosed herein are a system, method and apparatus for integrating multiple energy harvesting technologies into an umbrella platform. An inverted solar cell structure that harvests solar energy is combined into a single structure with a piezoelectric material that harvests kinetic energy in the form of rain or wind. Additional sources of energy may be harvested from electromagnetic waves as well as radio frequency energy. The harvested energy will be converted to electricity to charge an energy storage medium, such as a battery, that is embedded in the umbrella shaft and/or handle. A charging port near the handle of the umbrella allows personal electronic devices to be recharged via various adapters. Wireless charging of personal electronic device is also possible with the present energy harvesting system, method and apparatus.

The system, method and apparatus described herein, in the most general embodiment, include an umbrella platform which replaces the conventional waterproof canopy with a polymer solar cell and piezoelectric polyvinylidene difluoride (PVDF) combination device. No additional canvas is needed for the canopy; however, a canvas material may be added along with the solar cell and piezoelectric device. The umbrella is portable. When the umbrella is open, it may gather solar energy, kinetic energy, electromagnetic energy and radio frequency energy. The umbrella may be closed and carried between locations.

When the umbrella is closed, it may be used as a cane. As the user walks, the user may strike the ground with a depressible tip at the end of the umbrella. The depressible tip may replace the umbrella's ferrule. Alternatively, the depressible tip may be a part of the umbrella's ferrule. This striking action may cause the generation of electromagnetic energy. In this respect, the umbrella can harvest energy even when it is closed. As part of the umbrella canopy, the polymer solar cell may be stacked on top of the polymer piezoelectric material. Alternatively, strips of polymer solar cell structure may be printed next to strips of the polymer piezoelectric material via a roll-to-roll printing technique. It should be understood that other printing or manufacturing techniques could also be used to make the solar cell and polymer piezoelectric material, such as three-dimensional (3-D) printing and laser printing.

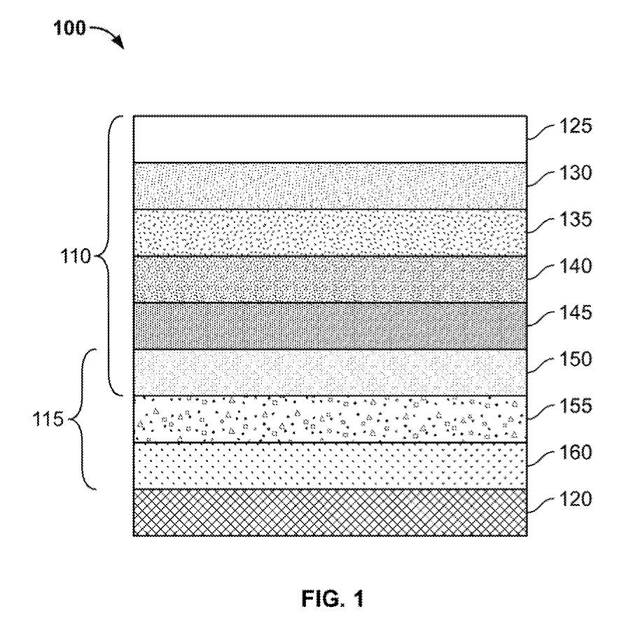

Referring now to FIG. 1, illustrated are canopy layers 100 of one embodiment of a multi-source energy harvesting system. The canopy layers 100 include a polymer solar cell 110 and kinetic energy harvesting device 115 underneath the solar panel 110. Ripstop canvas 120 may be added beneath the kinetic energy harvesting device 115 to provide protection to the canopy layers 100, whether the canopy layers 100 are incorporated into an umbrella or other structure.

The kinetic energy harvesting device 115 may be composed of polymer piezoelectric material including, for example, PVDF. The polymer piezoelectric material may be flexible, and may convert strain and stresses into electricity. The strains and stresses may result from wind and rain making contact with the polymer piezoelectric material of the energy harvesting device 115. If the solar panel 110 is composed of an inflexible or rigid material, and the solar panel 110 on top of the kinetic energy harvesting device. If a rigid solar panel is placed on top of the kinetic energy harvesting device 115, it may it will likely reduce the effectiveness

As shown in the non-limiting embodiment of FIG. 1, the polymer solar panel 110 includes multiple layers including a top layer 125 that is an environmental protective coating 125 to protect the canopy layers 100 from environmental damage and/or accelerated wear and tear. Such coatings are known in the art. A second layer, 130 is composed of aluminum, silver, or another material. A third layer 135 may be molybdenum tri-oxide. A fourth layer 140 may be composed of a six millimeter (6 m) thick positive temperature coefficient material (PTC6M). A fifth layer 150 may be composed of lead iron niobate (PFN). The sixth layer 150 may be an indium tin oxide (ITO) cathode layer, which may comprise a shared electrical lead between the polymer solar panel 110 and the kinetic energy harvesting device 115. The shared lead affords a less expensive, simpler, and smaller structure than a system with separate dedicated leads although the system would also work with multiple leads. The illustrated solar cell panel 110 is merely illustrative, and it should be understood that numerous other configurations are possible for the solar panel 110 and its shared electrical lead. The shared electrical lead 150 connects to a network of conductive electrical leads (not shown in FIG. 1) which feed into the shaft of the umbrella (not shown in FIG. 1).

As shown, the kinetic energy harvesting device 115 starts at a seventh layer of the multi-source energy harvesting system. Here, the seventh layer 155 is composed of a PVDF material. An eighth layer 160 is composed of aluminum or silver. The combination solar/kinetic energy harvesting device shown in FIG. 1 may be fabricated with roll-to-roll printing. Roll-to-roll printing may is typically accomplished in a manner similar to commercial ink jet printing ubstiuting polymer ink cartridges for color ink cartridges for a specific layer.

The polymer solar panel 110 shown in FIG. 1 may be replaced with any other suitable solar cell, including another polymer solar cell. The layer thicknesses of the materials used in the solar panel 110 and rain and wind energy harvesting device 115 may vary. The layer thicknesses of the layers for the solar panel 110 and the kinetic energy harvesting device 115 may be very small, e.g., on the order of 9 to 25 microns thick or as otherwise decided for a specific operating environment. Other possible embodiments include the use of multiple layers of material stacked together to target a particular function or performance characteristic.

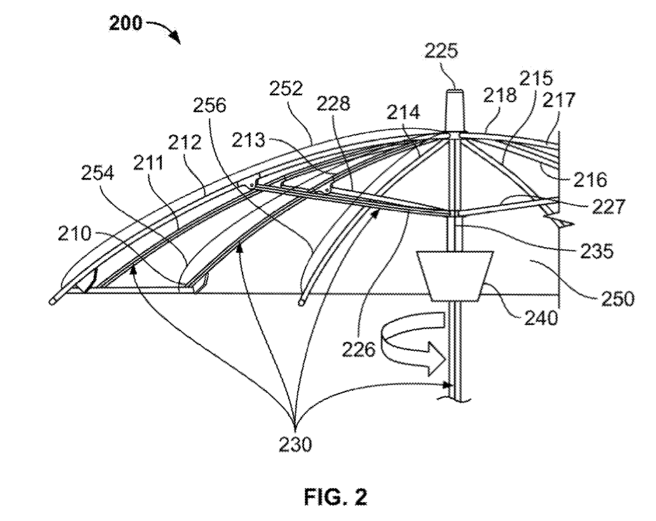

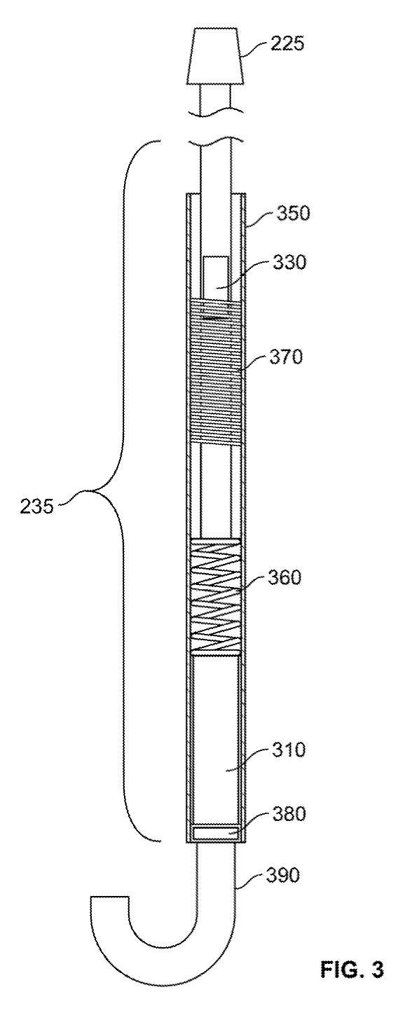

FIG. 2, illustrates a fragmentary and sectional view of a multi-source energy harvesting umbrella in accordance with one embodiment of the present disclosure. In the embodiment of FIG. 2, the canopy 250 of the umbrella 200 has been partially removed in order to expose various ribs and additional structure. Ribs 210, 211, 212, 213, 214, 215, 216, 217, 218 extend radially outward from ferrule 225. Ferrule 225 is disposed at the top center of umbrella 200 at one end of shaft 235. Additional ribs, generally referred to as stretchers, 226, 227, 228 are located about midway down the length of, and substantially perpendicular to the shaft 235 when the umbrella is in the open position. The umbrella 200 incorporates a network of conductive electrical leads 230. The electrical leads 230 may be any conductive material such as conductive polymers, carbon nanotubes, or other materials. The umbrella includes a shaft 235 disposed below the ferrule 225. Ferrule 225 may include a depressible umbrella tip that may be used to generate energy when the tip strikes the ground or other object, as described in greater detail herein below in connection with FIG. 3. In FIG. 2, the network of electrical leads 230 may extend from the ribs through the shaft 235 and down to the charging port (not shown in FIG. 2) in order to provide charging capability for personal electronic devices. Electrical leads 230 provide a pathway for all energy harvesting mechanisms, including solar, rain, wind, electromagnetic and radio frequency harvesting mechanisms, to share a single electrical bus. The electrical leads 230 may connect to a single electrical bus (not shown) that may be internal to the shaft 235. The umbrella 200 may also include a spinning canopy top in order to harvest wind energy. In an alternative embodiement the umbrella includes a miniature windmill 240 affixed to the shaft 235 of the umbrella. Canopy 250 is affixed to ribs 210, 211, 212, 213, 214, 215, 216, 217, and 218, Canopy 250 may incorporate a solar panel (not shown in FIG. 2), a kinetic energy harvesting (not shown in FIG. 2) or other energy harvesting devices (not shown in FIG. 2) suitable for incorporation into canopy 250.

In the illustration of FIG. 2, the structure 200 is shaped as a hand carried umbrella. However, it should be understood that the structure could take on a number of other forms. For example, the structure could be a flat surface that incorporates a grid of small solar cells or panels or be a patio umbrella. The profile geometry may also be as large as a roof canopy for a building structure. In lieu of the circular concave shape of the umbrella canopy structure shown in FIG. 2, the structure may be any shape, such as a triangle, square, pentagon, hexagon, circle, etc. Some elements are optional, such as the mechanical energy harvester described below, in those instances in which the shape of the structure or its intended operating environment.

As for the illustrative structure shown in FIG. 2, its umbrella shape may result in additional functionality. The portable umbrella structure 200 could also be easily adjusted by a user via the shaft 235 or handle (not shown) so as to direct the solar cell toward the sunlight so that more solar energy is collected at a given time.

A network of electrical leads 230 from the device canopy 250 may feed into the umbrella shaft 235 via the ribs 210, 211, 226 as shown in FIG. 2. The leads 230 may attach to a rechargeable battery (not shown) that may be disposed within the umbrella shaft 235 and/or handle (not shown in FIG. 2). A charging port (not shown) may be built into the umbrella shaft 235 or the bottom of an umbrella handle (not shown in FIG. 2). The charging port 380 can support a variety of personal devices such as telephones, tablets or laptops via appropriate adaptors.

An alternative embodiment includes an induction charging method added by designing the top canopy 250 shown in FIG. 2 to spin from wind forces. This energy harvesting method would operate similar to a windmill. Flaps 252, 254, 256 are included in order to aid the umbrella in harvesting energy using the additional induction charging method.

Another method of energy harvesting that can be incorporated into the umbrella is the capturing of radio frequency (RF) signals. In this instance, the shaft 235 of the umbrella may act as a monopole antenna. A circuit board may be disposed within shaft 235. The circuit board may be based on micro-electromechanical (MEMs) or commercially available technology, and may provide energy conversion of the electromagnetic waves. Personal electronic devices may be charged at a distance using radio frequency energy.

An input selector switch (not shown in FIG. 2) may also be disposed within shaft 235, and may be used to switch between various energy harvesting technologies. This switch may permit manual switching between the desired harvesting source and the rechargeable battery.

Referring now to FIG. 3, illustrated is a shaft 235 and handle 390 of a multi-source energy harvesting umbrella in accordance with another embodiment of the present disclosure. FIG. 3 schematically shows the relationship between the shaft 235, handle 390, and ferrule 225. Ferrule 225 is disposed on top of the shaft 235. FIG. 3 also schematically shows shaft where the rechargeable battery 310 resides in the shaft 235.

When the umbrella canopy 250 is closed and used as a cane, walking stick or staff, the spring-loaded depressible umbrella tip, which may be a part of ferrule 225, may push the magnet 330 which may freely move within the umbrella shaft 235. The depressible umbrella tip in ferrule 225 may launch the magnet through the shaft 350 as the tip 225 strikes the ground/floor. Gravity causes the magnet to fall back onto the spring 360. The spring 360 is incorporated in order to provide a mechanism for the magnet 330 to move through a wire coil 370. The depressible tip in ferrule 225 and magnet 330 move through the wire coil 370. Each of the depressible tip in ferrule 225, magnet 330 and wire coil 370, are disposed in the umbrella shaft 350. The up and down motion of the magnet 330 may cause a changing magnetic field and as a result, an electrical current may be formed in the wire coil 370. Thus, even when closed while the user is walking, the umbrella can continue to harvest energy. It should be understood that other mechanisms for moving the magnet 330 through the wire coil 370 are possible.

Once energy is harvested by the various energy harvesting devices in the umbrella apparatus, the energy will travel to the charging port 380 by way of conductive electrical leads (not shown in FIG. 3). After the energy travels through these leads (not shown in FIG. 3), it may move to wire coil 370 before being stored at rechargeable battery 310. The charging port 380, which is connected to rechargeable battery 310, may be used to supply power to a personal electronic device. Additional ports, or a series of ports, may be provided to charge multiple personal electronic devices. Examples of these personal electronic devices include mobile/cell phones, computer tablets, cameras, or portable music players charging port 380 may be a USB input, or other suitable input for establishing an electrical connection with a personal electronic device. Wireless charging is also possible through use of inductive energy harvesting and associated electromagnetic energy. Wireless charging may be accomplished using a base station charging plate which contains a coil of wire that creates a magnetic field as the current passes through. This magnetic field can induce an electrical current in an adjacent coil of wire in the umbrella shaft. Commercially available wireless charging solutions for smart phones from Powermat Technologies, of Neve Ilan, Israel can be adapted for use with the present umbrella, method and apparatus. Using the present system, method and apparatus, energy may be harvested throughout the day, and provide charge to the rechargeable battery throughout the day. In some cases, the rechargeable battery 310 may be trickle-charged throughout the day. Commercially available integrated circuits boards may be used to provide trickle-charging from the multiple energy harvesting sources to the rechargeable battery. Float-charging may also be used. Float-charging is similar to trickle charging but also includes additional circuitry to reduce the risk of over-charging and damaging the battery. A float charger may sense when a battery voltage is at the appropriate level and temporarily cease charging. The float charger may maintain the charge current near zero until it senses that the battery output voltage has fallen, at which point it may then resume charging. Umbrella handle 390 may be grasped by the user to carry the portable umbrella structure.

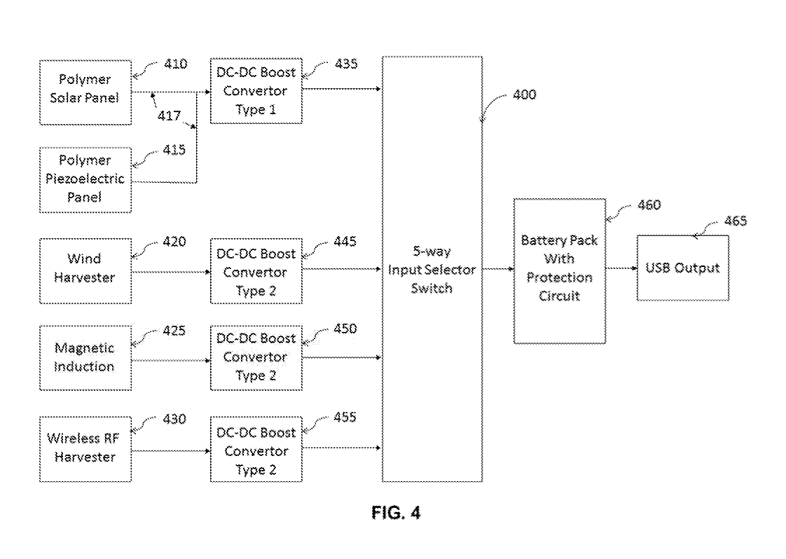

Various collection/storage methodologies may be used in conjunction with the system, method and apparatus disclosed herein. Referring now to FIG. 4, illustrated is a diagram of an energy storage flow in accordance with one embodiment of the present disclosure. As shown in FIG. 4 a five-way input selector switch 400 may be used to switch between various energy harvesting technologies. This switch 400 may permit manual switching between the desired harvesting source and the battery. Depending on conditions, energy consumption of the system may be minimized using this switch 400 since only the selected portion of the circuitry that is selected by the switch is powered. Switch 400 may be disposed within an umbrella shaft (not shown in FIG. 4), an umbrella handle (not shown in FIG. 4), in or near the canopy (not shown in FIG. 4), or in the umbrella's ribs (not shown in FIG. 4).

The five types of energy harvesters may provide input into the energy storage system. More particularly, a polymer solar panel 410, a piezoelectric panel 415, a wind harvester 420, a magnetic induction harvester 425 and a wireless radio frequency harvester 430 may provide input into the energy storage system. These energy harvesting devices may reside in an umbrella canopy and/or an umbrella shaft/handle or other suitable location on/near the umbrella.

DC-DC boost converters may be operably coupled to the energy harvesters. More particularly, polymer solar panel 410 and polymer piezoelectric panel 415 may be coupled, via a network of electrical leads 417, to a DC-DC boost converter 435 as commercially readily available. Solar cells/panels typically produce larger voltages and therefore do not require ultra-low voltage DC-DC converters like the other energy harvesting devices may require. A typical DC-DC convertor is sufficient for solar cells/panels. Likewise, the polymer piezoelectric panel 415 may not require the ultralow voltage converters that are used with the remaining energy harvesting devices, i.e., the wind harvester 420, the magnetic induction harvester 425, and the wireless radio frequency harvester 430.

The remaining three DC-DC boost converters 445, 450, 455 may, respectively, be coupled to the remaining three energy harvesters 420, 425, 430. These converters 445, 450, 455 may be of a second type commercially available with performance characteristics consistent with the design of the structure 200. Each of the converters 435, 445, 450, 455 may be operably coupled to switch 400 so that switch 400 operably connects any of the desired energy harvesting sources to the battery pack 460. Battery pack 460 may have a protection circuit. Battery pack 460 may be operably coupled to USB output 465 in order to provide power to the USB output from the desired energy source. In lieu of, or in addition to switch 400, an algorithm may be used to determine how to balance the selection and activity of all harvesting technologies involved.

It should be understood that different combinations of the energy harvesting technologies are possible. For example, it is possible to have only the solar energy harvesting combined with the electromagnetic energy harvesting. In this case, the resulting product might have the energy harvesting polymer canopy with the depressible umbrella tip. As another example, it is possible to have only the solar energy harvesting combined with the wind energy harvesting. In the second instance, the resulting product might include just the energy harvesting polymer canopy with a spinning umbrella top.

It will be understood that many additional changes in the details, materials, steps and arrangement of parts, which have been herein described and illustrated to explain the nature of the release system, may be made by those skilled in the art within the principle and scope of the invention as expressed in the appended claims.

We claim:

1. A multi-source energy harvesting system for charging electronic devices, comprising:
a solar energy harvesting device;
a kinetic energy harvesting device;
an electromagnetic energy harvesting device;
a port capable of charging a personal electronic device; and,
a rechargeable battery system configured to supply electrical power to the charging port,
wherein the rechargeable battery system is operably coupled to each of the charging port, the solar energy harvesting device, the kinetic energy harvesting device and the electromagnetic energy harvesting device;

2. The system of claim 1, further comprising:
an electrical lead shared by both the solar energy harvesting device and the kinetic energy harvesting device.

3. The system of claim 1,
wherein the solar energy harvesting device is a polymer solar cell.

4. The system of claim 3, wherein the solar energy harvesting device is stacked on top of the kinetic energy harvesting device.

5. The system of claim 1,
wherein the solar energy harvesting device is a polymer solar cell that is composed of multiple material layers; and
wherein the kinetic energy harvesting device is composed of multiple material layers.

6. The system of claim 1,
wherein the solar energy harvesting device includes strips of material,
the rain and wind energy harvesting device includes strips of material, and
the strips of the solar energy harvesting device are printed next to strips of the polymer piezoelectric material via roll-to-roll printing.

7. The system of claim 1, further comprising:
a radio frequency energy harvesting device.

8. The system of claim 1, wherein the electromagnetic energy harvesting device includes a magnet and a coil of wire.

9. A multi-source energy harvesting method for charging electronic devices, comprising:
converting solar energy into electrical energy with a polymer solar cell that is disposed on an umbrella canopy;
converting kinetic energy into electrical energy via a polymer piezoelectric material, disposed on an umbrella canopy;
converting electromagnetic energy into electrical energy with an inductive energy harvesting device that is disposed in an umbrella shaft;
storing the electrical energy in a rechargeable battery that is disposed in the umbrella shaft; and
supplying power to a charging port disposed in the umbrella shaft.

10. The method of claim 9, further comprising:
depressing a depressible umbrella tip disposed within the umbrella shaft, thus generating electromagnetic energy.

11. The method of claim 9, further comprising:
converting radio frequency energy into electrical energy via an antenna and circuit board that are disposed in the umbrella shaft.

12. A multi-source energy harvesting apparatus, comprising:
an umbrella canopy having:
a polymer solar cell device capable of converting solar energy into electrical energy;
a polymer piezoelectric kinetic energy harvesting device capable of converting kinetic energy into electrical energy; and,
a shared electrical lead that is operably coupled to both the polymer solar cell device and the kinetic energy harvesting device;
an umbrella shaft and handle having:
an inductive energy harvesting device capable of converting electromagnetic energy into electrical energy, the inductive energy harvesting device permitting wireless charging of one or more personal electronic devices;
a charging port capable of being operably coupled to a personal electronic device; and,
a rechargeable battery system configured to supply electrical power to the charging port;
wherein the rechargeable battery system is operably coupled to each of the charging port, the solar energy harvesting device, the kinetic energy harvesting device and the inductive energy harvesting device; and,
ribs, that include a plurality of electrical leads operably coupled to the rechargeable battery system and the charging port that extend from the umbrella shaft and supports the canopy when open
wherein the multi-source energy harvesting apparatus is capable of storing the electrical energy in the rechargeable battery, or consuming the electrical energy to charge a personal electronic device.

13. The apparatus of claim 12, wherein the polymer solar cell device is stacked on top of the kinetic energy harvesting device.

14. The apparatus of claim 12, wherein the polymer solar device is composed of strips of material and the kinetic energy harvesting device includes strips of material, and the strips of material for the polymer solar cell device are printed next to strips of material for the polymer piezoelectric material via roll-to-roll printing.

15. The apparatus of claim 12, further comprising:
a radio frequency energy harvesting device that is capable of converting radio frequency energy into electrical energy.

16. The apparatus of claim 12, further comprising:
a depressible umbrella tip disposed within the umbrella shaft which, when depressed, is capable of causing the generation of electromagnetic energy.

17. The umbrella device of claim 12, further comprising:
another inductive charging device capable of converting wind energy into electrical energy based on a spinning umbrella canopy.

18. The umbrella device of claim 15, further comprising an input selector switch configured to permit the manual selection of one of the polymer solar cell device, the kinetic energy harvesting device, the inductive energy harvesting device and the radio frequency energy harvesting device for input to the rechargeable battery.
